(19) United States
(12) Patent Application Publication
(10) Pub. No.: US 2026/0123343 A1
(43) Pub. Date: Apr. 30, 2026

(54) METHOD OF ALIGNING SEMICONDUCTOR WAFER IN SCANNER DEVICE

(71) Applicant: Samsung Electronics Co., Ltd., Suwon-si (KR)

(72) Inventors: Woo-Yong JUNG, Suwon-si (KR); Seungyoon LEE, Suwon-si (KR); Heonju LEE, Suwon-si (KR); Chan HWANG, Suwon-si (KR)

(73) Assignee: Samsung Electronics Co., Ltd., Suwon-si (KR)

(21) Appl. No.: 19/329,694

(22) Filed: Sep. 16, 2025

(30) Foreign Application Priority Data
Oct. 29, 2024 (KR) 10-2024-0150015

(51) Int. Cl. H01L 21/68; H01L 21/687; H01L 23/544

(52) U.S. Cl. CPC H10P 72/53; H10P 72/7604; H10W 46/00; H10W 46/301

(57) ABSTRACT

Disclosed are methods of aligning a semiconductor wafer in a scanner device. In a method of aligning a semiconductor wafer in a scanner device, a first mark pair includes two marks among a plurality of marks of a semiconductor wafer. A plurality of mark pairs including the first mark pair are set by performing a geometric transformation at least once on the first mark pair. A plurality of coarse model parameters are generated by performing a coarse wafer alignment (COWA) based on each of the plurality of mark pairs. A fine model parameter is generated by performing a fine wafer alignment (FIWA) based on the plurality of marks. Whether an alignment of the semiconductor wafer is successful is determined based on the plurality of coarse model parameters and the fine model parameter. A subsequent process is performed based on a determination that the alignment of the semiconductor wafer is successful.

### CROSS-REFERENCE TO RELATED APPLICATIONS

This application claims priority under 35 U.S.C. § 119 to Korean Patent Application No. 10-2024-0150015 filed on Oct. 29, 2024, in the Korean Intellectual Property Office, the disclosures of which are incorporated by reference herein in their entireties.

### BACKGROUND

Example embodiments of the present disclosure described herein relate to semiconductor devices, and more particularly, relate to methods of aligning a semiconductor wafer in a scanner device.

In the photolithography process for manufacturing semiconductor devices, light is irradiated through a mask or a reticle on a semiconductor wafer coated with photoresist to form a specific pattern on the semiconductor wafer.

In this photolithography process, alignment of the semiconductor wafer should be performed in advance to precisely form a specific pattern on the semiconductor wafer. As semiconductor processes become more refined, to manufacture higher-quality semiconductor devices, the importance of a semiconductor wafer alignment is increasing.

### SUMMARY

Some example embodiments of the present disclosure provide methods of aligning a semiconductor wafer in a scanner device, which improves the success rate of a semiconductor wafer alignment.

According to an example embodiment of the present disclosure, a method of aligning a semiconductor wafer in a scanner device includes performing a geometric transformation at least once on a first mark pair including two marks among a plurality of marks of a semiconductor wafer to set a plurality of mark pairs including the first mark pair, performing a coarse wafer alignment (COWA) based on each of the plurality of mark pairs to generate a plurality of coarse model parameters, performing a fine wafer alignment (FIWA) based on the plurality of marks to generate a fine model parameter, determining whether an alignment of the semiconductor wafer is successful based on the plurality of coarse model parameters and the fine model parameter, and performing a subsequent process based on a determination that the alignment of the semiconductor wafer is successful.

According to an example embodiment of the present disclosure, a method of aligning a semiconductor wafer in a scanner device includes performing a geometric transformation at least once on a first mark pair including two marks among a plurality of marks of a semiconductor wafer to set a plurality of mark pairs including the first mark pair, performing a coarse wafer alignment (COWA) and a fine wafer alignment (FIWA) based on the plurality of mark pairs and the plurality of marks to generate a plurality of model parameters, determining whether an alignment of the semiconductor wafer is successful based on the plurality of model parameters, and performing a subsequent process based on a determination that the alignment of the semiconductor wafer is successful.

According to an example embodiment of the present disclosure, a method of aligning a semiconductor wafer in a scanner device includes performing a rotational transformation or a proportional transformation at least once on a first mark pair including two marks among a plurality of marks of a semiconductor wafer to set a second mark pair, performing a coarse wafer alignment (COWA) based on the first mark pair to generate a first coarse model parameter, performing a fine wafer alignment (FIWA) based on the plurality of marks to generate a fine model parameter, determining whether an alignment of the semiconductor wafer is successful based on the first coarse model parameter and the fine model parameter, performing a COWA based on the second mark pair to generate a second coarse model parameter based on a determination that the alignment of the semiconductor wafer is not successful, and determining whether the alignment of the semiconductor wafer is successful based on the second coarse model parameter and the fine model parameter.

According to an example embodiment of the present disclosure, a scanner device included in a photolithography equipment includes an alignment unit having an alignment simulator and an alignment verifier, the alignment simulator configured to perform alignment by performing a geometric transformation at least once on a first mark pair including two marks among a plurality of marks of a semiconductor wafer to set a plurality of mark pairs including the first mark pair, performing a coarse wafer alignment (COWA) based on each of the plurality of mark pairs to generate a plurality of coarse model parameters, and performing a fine wafer alignment (FIWA) based on the plurality of marks to generate a fine model parameter, the alignment verifier configured to determine whether the alignment is successful based on the plurality of coarse model parameters and the fine model parameter.

The scanner device may further include an exposure unit configured to perform an exposure process on the semiconductor wafer.

### BRIEF DESCRIPTION OF THE FIGURES

The above and other objects and features of the present disclosure will become apparent by describing in detail some example embodiments thereof with reference to the accompanying drawings.

FIG. 1 is a block diagram illustrating a photolithography equipment including a scanner device, which is configured to perform a semiconductor wafer alignment method, according to an example embodiment of the present disclosure.

FIG. 2 is a diagram for describing a semiconductor wafer of FIG. 1.

FIG. 3 is a flowchart illustrating a semiconductor wafer alignment method, according to an example embodiment of the present disclosure.

FIG. 4 is a diagram for describing a plurality of marks, according to an example embodiment.

FIG. 5 is a block diagram illustrating an example embodiment of an alignment unit of FIG. 1.

FIG. 6 is a block diagram illustrating an example embodiment of an alignment simulator of FIG. 5.

FIG. 7 is a flowchart illustrating an example embodiment of an operation of the mark generator of FIG. 6.

FIG. 8 is a diagram for describing an example embodiment of the first mark pair of FIG. 3.

FIG. 9 is a diagram for describing an example embodiment of the geometric transformation of FIG. 3.

FIG. 10 is a diagram for describing an example embodiment of the plurality of mark pairs of FIG. 3.

FIG. 11 is a diagram for describing an example embodiment of the plurality of coarse model parameters and the fine model parameter of FIG. 3.

FIG. 12 is a flowchart illustrating an example embodiment of an operation of the alignment verifier of FIG. 5.

FIGS. 13A, 13B, and 13C are diagrams for describing a process for determining whether alignment of a semiconductor wafer is successful.

FIG. 14 is a flowchart illustrating a semiconductor wafer alignment method, according to an example embodiment of the present disclosure.

FIG. 15 is a flowchart illustrating a semiconductor wafer alignment method, according to an example embodiment of the present disclosure.

### DETAILED DESCRIPTION

Hereinafter, some example embodiments of the present disclosure will be described in detail and clearly to such an extent that an ordinary one in the art easily implements the present disclosure.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C, or any combination thereof. Likewise, A and/or B means A, B, or A and B.

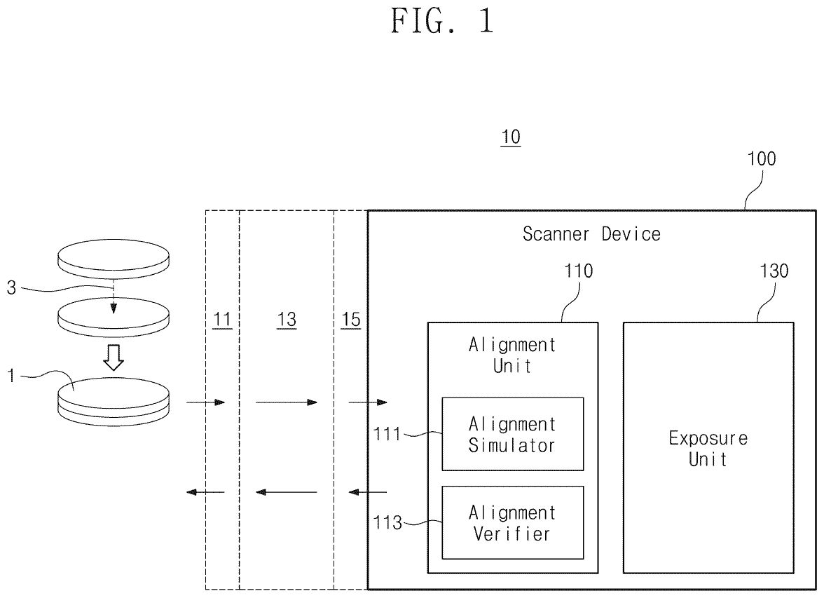

FIG. 1 is a block diagram illustrating a photolithography equipment including a scanner device, which is configured to perform a semiconductor wafer alignment method, according to an example embodiment of the present disclosure.

Referring to FIG. 1, a photolithography equipment 10 may include a scanner device 100. The scanner device 100 may include an alignment unit 110 and an exposure unit 130. The alignment unit 110 may include an alignment simulator 111 and an alignment verifier 113.

The alignment unit 110 may perform alignment on a semiconductor wafer 1 delivered from the outside, and may provide the semiconductor wafer 1 to the exposure unit 130 based on a determination that the alignment is successful. The alignment may be performed by the alignment simulator 111, and the determination that the alignment is successful may be performed by the alignment verifier 113.

The exposure unit 130 may perform an exposure process on a semiconductor wafer 1 delivered from the alignment unit 110, and provide the semiconductor wafer 1 on which the exposure process is performed to the outside.

In an example embodiment, the photolithography equipment 10 may further include a loading/unloading unit 11, a spinner device 13, and an interface unit 15. The loading/unloading unit 11 may load or unload a cassette loaded with the semiconductor wafer 1, and when the cassette is loaded, may provide the loaded semiconductor wafer 1 to the spinner device 13. The spinner device 13 may perform a coating process and a baking process on the semiconductor wafer 1 delivered from the loading/unloading unit 11, and may provide the semiconductor wafer 1 on which the coating process of a photoresist material and the baking process are completed to the scanner device 100 through the interface unit 15. The spinner device 13 may also perform a developing process on the semiconductor wafer 1 delivered from the scanner device 100 through the interface unit 15, and may provide the developed semiconductor wafer 1 to the loading/unloading unit 11.

The alignment of the semiconductor wafer 1 by the alignment unit 110 should be successful before performing the exposure process by the exposure unit 130. When the alignment of the semiconductor wafer 1 is not successful, the progress of the exposure process is stopped, the subsequent process after the alignment may not be performed, and/or the semiconductor wafer 1 in this case may be discarded.

The semiconductor wafer 1 may include a plurality of marks. The alignment unit 110 may irradiate light onto all or some of the plurality of marks, and may perform the alignment of the semiconductor wafer 1 based on the reflected light. For example, the alignment performed by irradiating light onto some of the plurality of marks may be referred to as “coarse wafer alignment (COWA)”, and the alignment performed by irradiating light onto all of the plurality of marks may be referred to as “fine wafer alignment (FIWA)”. The alignment unit 110 may select some of the plurality of marks for the COWA, and may irradiate light to the selected marks in the process of performing the COWA. A coarse alignment of the semiconductor wafer 1 may be performed by the COWA, and a fine alignment of the semiconductor wafer 1 may be performed by the FIWA. The number of marks used in each of the COWA and the FIWA are disclosed for example only.

The results of the alignment unit 110 performing the COWA and the FIWA may be expressed as a plurality of model parameters. For example, the alignment unit 110 may perform the COWA to generate a coarse model parameter, and may perform the FIWA to generate a fine model parameter. The alignment unit 110 may determine whether the alignment of the semiconductor wafer 1 is successful based on the coarse model parameter and the fine model parameter.

In an example embodiment, the semiconductor wafer 1 may be one in which a wafer bonding process (e.g., 3) is performed on a plurality of wafers. In this case, the semiconductor wafer 1 may be deformed by the wafer bonding process and the accompanying high-temperature thermal process, resulting in various three-dimensional shapes different from the original shape of the semiconductor wafer 1.

In the alignment method of the semiconductor wafer according to the example embodiments of the present disclosure, the scanner device may perform the COWA by selecting some of the plurality of marks of the semiconductor wafer and may perform the FIWA on the plurality of marks. The selection of some of the plurality of marks for the COWA may affect the model values that the coarse model parameters may have, thereby affecting the success or the failure of the semiconductor wafer alignment. The scanner device may improve the success rate of the semiconductor wafer alignment by selecting the marks for the COWA according to the alignment method of the semiconductor wafer according to the example embodiments of the present disclosure, considering the shape that the semiconductor wafer may have. Therefore, subsequent processes of the semiconductor wafer, including the exposure process, may proceed more smoothly.

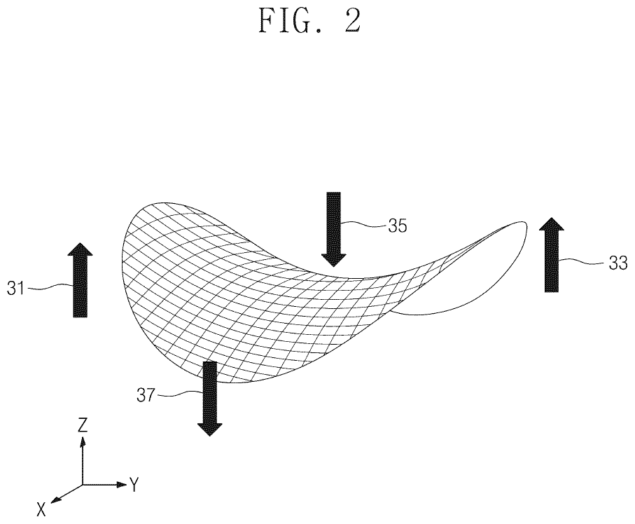

FIG. 2 is a diagram for describing a semiconductor wafer of FIG. 1.

In FIG. 2, directions X, Y, and Z that are orthogonal to each other are illustrated. The directions X and Y may be horizontal directions, and the direction “Z” may be a vertical direction perpendicular to both X and Y directions.

Referring to FIG. 2, the semiconductor wafer (e.g., 1 in FIG. 1) may have a shape in which it is bent in a positive (+) vertical direction “Z” near both edges in the direction “Y” (31 and 33), and in a negative (−) vertical direction “Z” near both edges in the direction “X” (35 and 37).

As described above with reference to FIG. 1, the semiconductor wafer may be a semiconductor wafer on which a wafer bonding process is performed, the wafer bonding process may involve a thermal process for adding bumps to a wafer substrate and a bonding process using these bumps, and the semiconductor wafer on which the thermal process and the bonding process are performed may be deformed as illustrated in FIG. 2 to have a three-dimensional shape in the shape of a saddle. In other words, the semiconductor wafer may be formed by performing a wafer bonding process of bonding one semiconductor sub-wafer to another semiconductor sub-wafer.

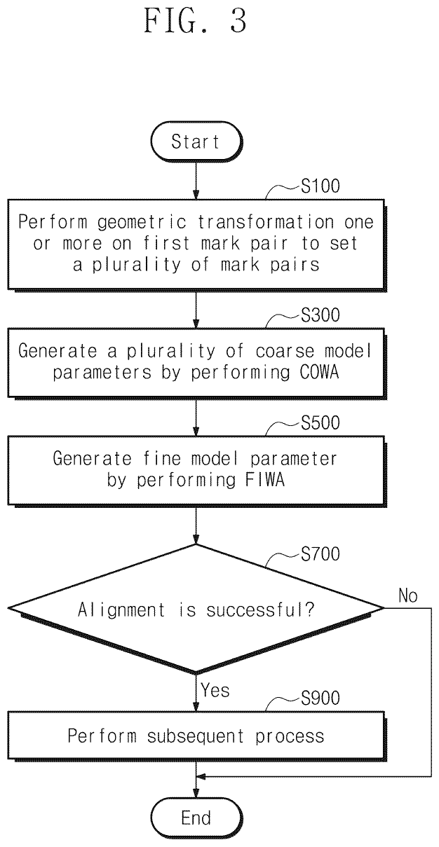

FIG. 3 is a flowchart illustrating a semiconductor wafer alignment method, according to an example embodiment of the present disclosure.

Referring to FIGS. 1 and 3, a geometric transformation may be performed on a first mark pair at least once to set a plurality of mark pairs including the first mark pair (S100).

In an example embodiment, the first mark pair may include two marks among a plurality of marks of a semiconductor wafer. The semiconductor wafer may include a plurality of semiconductor chips, and the plurality of marks may be formed on a scribe lane that distinguishes the plurality of semiconductor chips, but the scope of the present disclosure is not limited thereto. The semiconductor wafer may include a plurality of shot regions, and each shot region may include one or more semiconductor chips, may be a region that becomes a unit of an exposure process, and may include one or more marks, but the scope of the present disclosure is not limited thereto. For example, the number of the plurality of marks may be greater than or equal to the number of the plurality of shot regions.

A plurality of coarse model parameters may be generated by performing the COWA based on each of the plurality of mark pairs (S300).

Based on the plurality of marks, the FIWA may be performed to generate fine model parameters (S500).

Based on the above plurality of coarse model parameters and the fine model parameter, it may be determined whether the alignment of the semiconductor wafer is successful (S700).

In an example embodiment, each of the plurality of coarse model parameters may include model values, the fine model parameter may also include model values, and based on differences between the corresponding model values in the model values of the plurality of coarse model parameters and the model values of the fine model parameter (e.g., differences between model values of a first coarse model parameter among the plurality of coarse model parameters and respective ones of model values of the fine model parameter corresponding thereto), it may be determined whether the alignment of the semiconductor wafer is successful.

Based on the determination that the alignment of the semiconductor wafer is successful (S700: YES), a subsequent process may be performed (S900).

In an example embodiment, S100, S300, S500 and S700 may be performed by the alignment unit 110 of the scanner device 100, and S900 may be performed by the exposure unit 130 or the spinner device 13 of the scanner device 100.

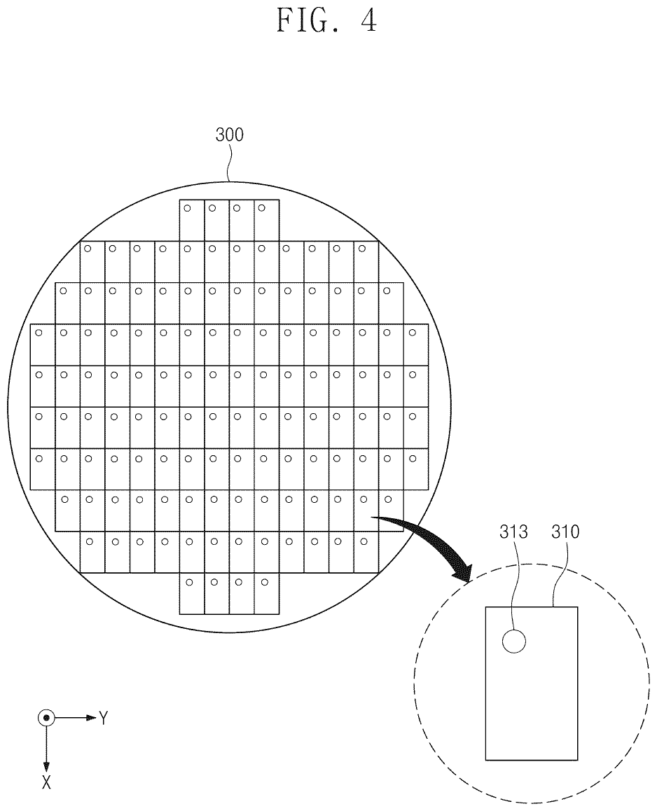

FIG. 4 is a diagram for describing a plurality of marks, according to an example embodiment.

Referring to FIG. 4, a semiconductor wafer 300 may include a plurality of semiconductor chips, and a plurality of shot regions, each of which includes one or more semiconductor chips, may be set on the semiconductor wafer 300.

In an example embodiment, each shot region 310 may include one mark (e.g., 313), but the number of marks included in one shot region 310 is for illustrative purposes only. As described above with reference to FIG. 3, each shot region may be a region that becomes a unit of an exposure process and may include one or more marks.

In an example embodiment, even though the mark 313 is illustrated in the form of a single solid circle in FIG. 4, the mark 313 may include a plurality of sub-marks that may be used to individually calculate displacement in each of the direction “X”and the direction “Y”.

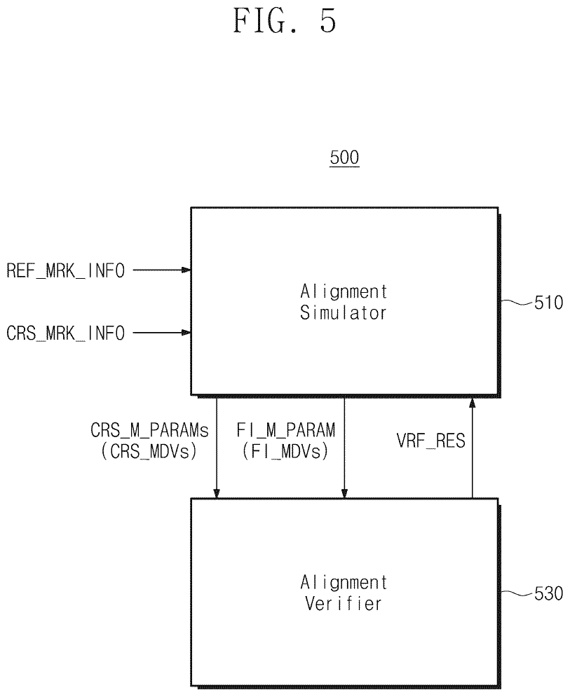

FIG. 5 is a block diagram illustrating an example embodiment of an alignment unit of FIG. 1.

Referring to FIG. 5, an alignment unit 500 may include an alignment simulator 510 and an alignment verifier 530. The alignment unit 500 may correspond to the alignment unit 110 of FIG. 1, and the alignment simulator 510 and the alignment verifier 530 may correspond to the alignment simulator 111 and the alignment verifier 113 of FIG. 1, respectively.

The alignment simulator 510 may receive reference mark information REF_MRK_INFO and coarse mark information CRS_MRK_INFO. The alignment simulator 510 may generate a plurality of coarse model parameters CRS_M_PARAMs and a fine model parameter FI_M_PARAM based on the reference mark information REF_MRK_INFO and the coarse mark information CRS_MRK_INFO, and may provide the plurality of coarse model parameters CRS_M_PARAMs and the fine model parameter FI_M_PARAM to the alignment verifier 530.

In an example embodiment, the reference mark information REF_MRK_INFO may include information associated with all of the plurality of marks. For example, the reference mark information REF_MRK_INFO may include ideal coordinate values of each of the plurality of marks, but the scope of the present disclosure is not limited thereto.

The coarse mark information CRS_MRK_INFO may include information for setting a plurality of mark pairs among the plurality of marks. For example, the coarse mark information CRS_MRK_INFO may include the number of the plurality of mark pairs, coordinate values for setting a first mark pair among the plurality of marks, a rotation angle or reduction ratio for performing a geometric transformation from the first mark pair, but the scope of the present disclosure is not limited thereto.

In an example embodiment, each of the plurality of coarse model parameters CRS_M_PARAMs may include model values CRS_MDVs, and the fine model parameter FI_M_PARAM may also include model values FI_MDVs. The model values CRS_MDVs and the model values FI_MDVs may include values that correspond to each other. For example, the model values CRS_MDVs may include values related to a wafer magnification, a wafer rotation, a non-orthogonality, and/or a wafer translation, and the same applies to the model values FI_MDVs.

The alignment verifier 530 may receive the plurality of coarse model parameters CRS_M_PARAMs and the fine model parameter FI_M_PARAM. The alignment verifier 530 may generate a verification result VRF_RES based on the plurality of coarse model parameters CRS_M_PARAMs and the fine model parameters FI_M_PARAM, and may provide the verification result VRF_RES to the alignment simulator 510.

In an example embodiment, the verification result VRF_RES may indicate whether the alignment of the semiconductor wafer is successful.

Although not shown in FIG. 5, the alignment simulator 510 may receive a semiconductor wafer, may irradiate light to a plurality of marks or a plurality of mark pairs formed on the semiconductor wafer based on the reference mark information REF_MRK_INFO and the coarse mark information CRS_MRK_INFO, and may generate the plurality of coarse model parameters CRS_M_PARAMs and the fine model parameter FI_M_PARAM based on the reflected light. The alignment simulator 510 may provide the semiconductor wafer to a subsequent device (e.g., 130 or 13 of FIG. 1) for a subsequent process when the verification result VRF_RES by the alignment verifier 530 indicates that the alignment of the semiconductor wafer is successful.

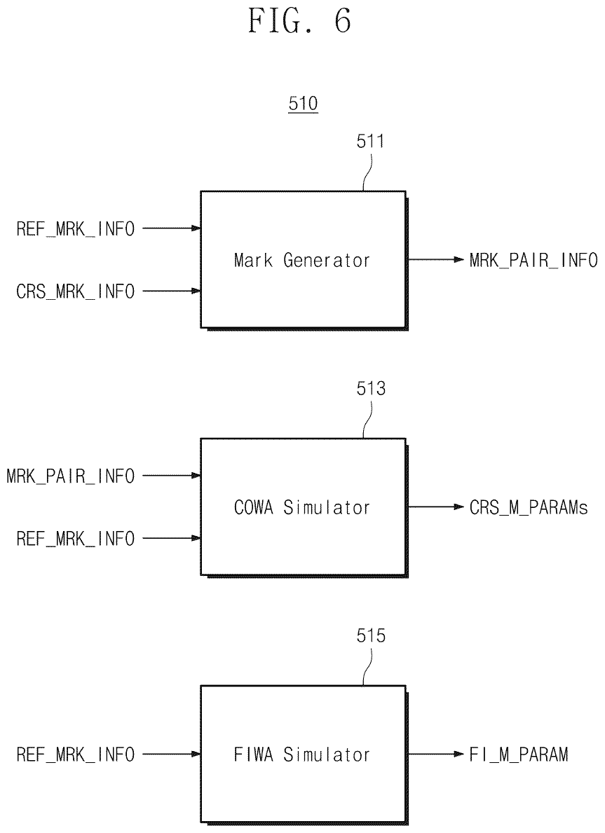

FIG. 6 is a block diagram illustrating an example embodiment of an alignment simulator of FIG. 5.

Referring to FIGS. 5 and 6, the alignment simulator 510 may include a mark generator 511, a COWA simulator 513, and a FIWA simulator 515.

The mark generator 511 may generate mark pair information MRK_PAIR_INFO based on the reference mark information REF_MRK_INFO and the coarse mark information CRS_MRK_INFO.

In an example embodiment, the mark pair information MRK_PAIR_INFO may include coordinate values of a plurality of mark pairs for performing the COWA, but the scope of the present disclosure is not limited thereto.

The COWA simulator 513 may generate the plurality of coarse model parameters CRS_M_PARAMs based on the mark pair information MRK_PAIR_INFO and the reference mark information REF_MRK_INFO.

The FIWA simulator 515 may generate the fine model parameter FI_M_PARAM based on the reference mark information REF_MRK_INFO.

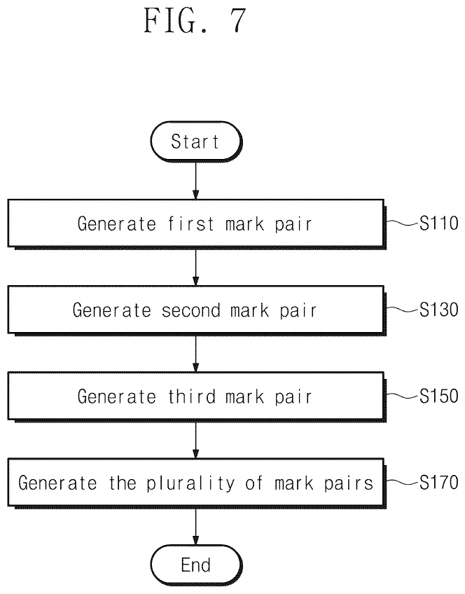

FIG. 7 is a flowchart illustrating an example embodiment of an operation of a mark generator 511 of FIG. 6.

Referring to FIG. 7, a first mark pair including two marks among a plurality of marks of a semiconductor wafer may be generated (S110).

A second mark pair may be generated by performing a geometric transformation on the first mark pair at least once (S130).

A third mark pair may be generated by performing a geometric transformation on the second mark pair at least once (S150).

A plurality of mark pairs including the first mark pair, the second mark pair, and the third mark pair may be generated (S170).

In an example embodiment, the COWA may be performed based on each of the first mark pair, the second mark pair, and the third mark pair.

In FIG. 7, an example embodiment in which three mark pairs are generated is illustrated, but the scope of the present disclosure is not limited thereto. As described below, the mark generator 511 of FIG. 6 may generate 10 or more mark pairs and may perform the COWA on each of the mark pairs to generate a plurality of coarse model parameters.

In an example embodiment, the COWA may be performed sequentially on each of the first mark pair, the second mark pair, and the third mark pair, but the scope of the present disclosure is not limited thereto. In another example embodiment, only the COWA may be performed on the first mark pair, whether alignment of the semiconductor wafer is successful may be determined based on the result of performing the COWA on the first mark pair, and when alignment of the semiconductor wafer is not successful, the second mark pair may be generated and the COWA may be performed on the second mark pair. Based on the result of performing the COWA on the second mark pair, whether alignment of the semiconductor wafer is successful may be determined, and when alignment of the semiconductor wafer is not successful again, the third mark pair may be generated and the COWA may be performed on the third mark pair.

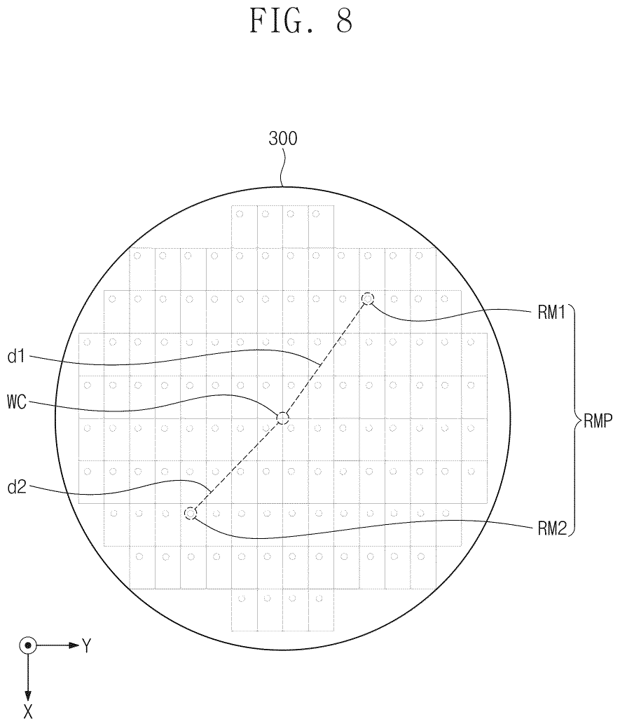

FIG. 8 is a diagram for describing an example embodiment of a first mark pair of FIG. 3.

Referring to FIGS. 4, 6, and 8, the mark generator 511 may select two marks RM1 and RM2 arranged at the same distance (e.g., d1 and d2) from a center WC of the semiconductor wafer 300, and may set a first mark pair RMP including the selected marks RM1 and RM2.

In an example embodiment, the marks RM1 and RM2 may be point-symmetrical with respect to the center WC of the semiconductor wafer 300. For example, a virtual line connecting the marks RM1 and RM2 in a straight line may pass through the center WC of the semiconductor wafer 300.

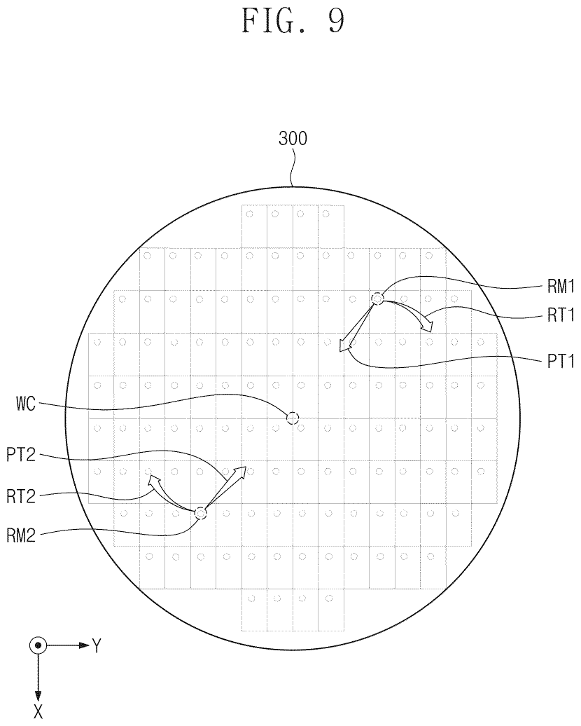

FIG. 9 is a diagram for describing an example embodiment of the geometric transformation of FIG. 3.

Referring to FIGS. 4, 6, and 9, the mark generator 511 may perform a geometric transformation on the first mark pair RMP at least once to set a plurality of mark pairs including the first mark pair RMP.

In an example embodiment, the plurality of mark pairs may be marks selected by the alignment unit 110 from among the plurality of marks for the COWA, as described above with reference to FIG. 1.

In an example embodiment, the geometric transformation may include a rotational transformation and a proportional transformation. For example, the mark generator 511 may perform a rotational transformation RT1 on the mark RM1 and a rotational transformation RT2 on the mark RM2 to set the plurality of mark pairs. For example, the mark generator 511 may also perform a proportional transformation PT1 on the mark RM1 and a proportional transformation PT2 on the mark RM2 to set the plurality of mark pairs.

In an example embodiment, the plurality of mark pairs may be regular within the semiconductor wafer 300. For example, the number of the plurality of mark pairs may be “N” (where “N” is an integer greater than or equal to 2), and in this case, the rotation angle according to the rotational transformation for the first mark pair may be 360/N degrees.

In an example embodiment, the proportional transformation may include a reduction transformation, but the scope of the present disclosure is not limited thereto. In another example embodiment, the proportional transformation may further include an enlargement transformation.

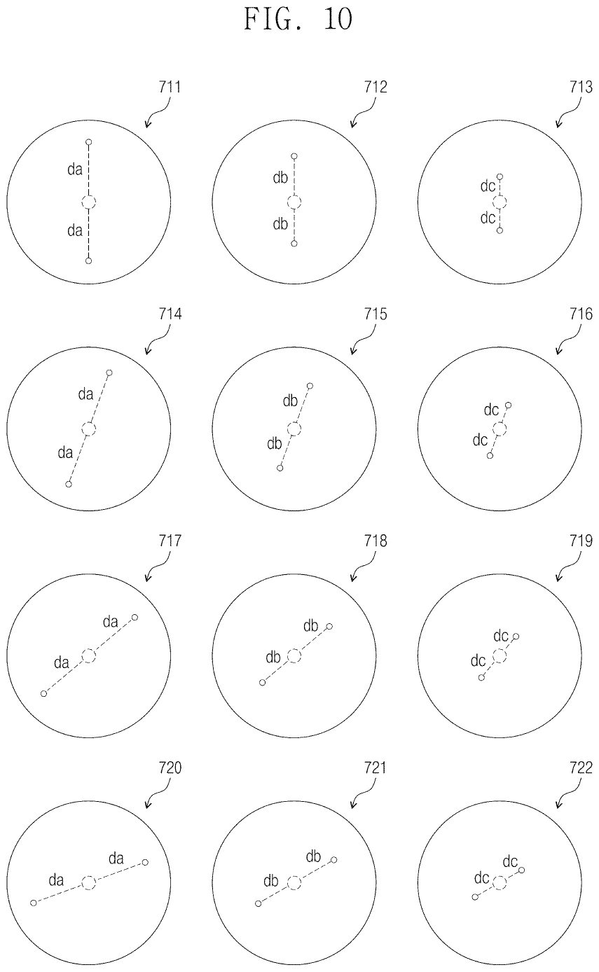

FIG. 10 is a diagram for describing an example embodiment of the plurality of mark pairs of FIG. 3.

In FIG. 10, a plurality of wafers 711, 712, 713, 714, 715, 716, 717, 718, 719, 720, 721, and 722 are illustrated, and each of the plurality of wafers 711 to 722 may correspond to the semiconductor wafers illustrated in FIG. 4, FIG. 8, and FIG. 9. Each of the two solid circles included in each of the plurality of wafers 711 to 722 may correspond to the mark 313 described above with reference to FIG. 4. Each of da, db, and dc illustrated between the center and the marks of each of the plurality of wafers 711 to 722 may represent the distance between the center and each of the marks.

In an example embodiment, marks illustrated on the wafer 711 are set as the first mark pair RMP described above with reference to FIGS. 8 and 9, and mark pairs illustrated on the remaining wafers 712 to 722 may be set by performing the geometric transformation on the first mark pair RMP at least once. For example, mark pairs illustrated on the wafers 714, 717, and 720 may be set by performing the rotational transformation on the first mark pair RMP at least once. For example, mark pairs illustrated on the remaining wafers 712, 713, 715, 716, 718, 719, 721, and 722 may be set by performing the proportional transformation on the mark pairs illustrated on corresponding ones of the wafers 711, 714, 717, and 720, respectively, at least once.

For example, the mark pair illustrated on the wafer 714 may be set by performing the rotational transformation once on the first mark pair RMP illustrated on the wafer 711, and the mark pair illustrated on the wafer 717 may be set by performing the rotational transformation twice on the first mark pair RMP. For example, the mark pair illustrated on the wafer 717 may be set by performing the rotational transformation once on the mark pair illustrated on the wafer 714.

For example, the mark pair illustrated on the wafer 712 may be set by performing the proportional transformation once on the first mark pair RMP, and the mark pair illustrated on the wafer 713 may be set by performing the proportional transformation twice on the first mark pair RMP. For example, the mark pair illustrated on the wafer 713 may also be set by performing the proportional transformation once on the mark pair illustrated on the wafer 712.

In an example embodiment, the rotation angle according to the rotational transformation with respect to the first mark pair RMP may be the same as or substantially similar to the rotation angle according to the rotational transformation with respect to the mark pair illustrated on the wafer 714 such that the plurality of mark pairs are regularly arranged within the semiconductor wafer, but the scope of the present disclosure is not limited thereto. In another example embodiment, the rotation angle according to the rotational transformation with respect to the first mark pair RMP may be different from the rotation angle according to the rotational transformation with respect to the mark pair illustrated on the wafer 714.

In an example embodiment, the reduction ratio according to the proportional transformation with respect to the first mark pair RMP such that the plurality of mark pairs are regularly arranged within the semiconductor wafer may be less than the reduction ratio according to the proportional transformation with respect to the mark pair illustrated on the wafer 712, but the scope of the present disclosure is not limited thereto. In another example embodiment, the reduction ratio according to the proportional transformation with respect to the first mark pair RMP may also be the same as or substantially similar to the reduction ratio according to the proportional transformation with respect to the mark pair illustrated on the wafer 712.

The mark pairs illustrated on the remaining wafers 715, 716, 718, 719, 720, 721, and 722 may also be set in a similar manner to the above-described manner.

For the convenience of description, the mark pairs are illustrated separately for each of the plurality of wafers 711 to 722, but all of the mark pairs illustrated in the plurality of wafers 711 to 722 may be included in the plurality of mark pairs described above with reference to FIG. 9.

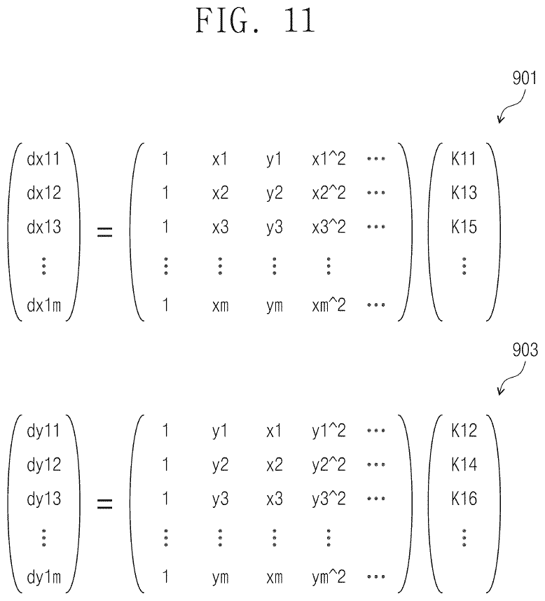

FIG. 11 is a diagram for describing an example embodiment of the plurality of coarse model parameters and the fine model parameter of FIG. 3.

In FIG. 11, two matrix equations 901 and 903 are illustrated.

Referring to FIG. 11, in the right-hand side of each of the matrix equations 901 and 903, (x1, y1), (x2, y2), (x3, y3) . . . , and (xm, ym) (where “m” is an integer greater than or equal to 4) may represent ideal coordinate values. For example, the (x1, y1) etc. may be ideal coordinate values of marks included in the plurality of mark pairs described above with reference to FIG. 8, FIG. 9, and FIG. 10, etc. when performing the COWA. For example, the (x1, y1) etc. may be ideal coordinate values of the plurality of marks described above with reference to FIG. 1, etc. when performing the FIWA.

In the left-hand side of each of the matrix equations 901 and 903, (dx11, dy11), (dx12, dy12), (dx13, dy13), . . . , and (dx1m, dy1m) may be displacement values generated from the plurality of mark pairs or the plurality of marks as a result of performing the COWA or the FIWA. For example, as described above with reference to FIG. 1, the (dx11, dy11) etc. may be differences between the coordinate values of the plurality of mark pairs or the plurality of marks, which are measured based on the light reflected after irradiating light on the plurality of mark pairs or the plurality of marks, and the ideal coordinate values.

In the right-hand side of each of the matrix equations 901 and 903, K11, K12, K13, K14, K15, K16, etc. may be parameters derived by applying a least square estimation or a weighted least square estimation.

In an example embodiment, the derived parameters may be the coarse model parameters or the fine model parameter described above with reference to FIG. 1, FIG. 3, etc. For example, the parameters derived based on the matrix equations 901 and 903 as a result of performing the COWA may be the coarse model parameters, and the parameters derived based on the matrix equations 901 and 903 as a result of performing the FIWA may be the fine model parameter.

In an example embodiment, the derived parameters may correspond to the model values CRS_MDVs or the model values FI_MDVs described above with reference to FIG. 5, and may include values associated with the wafer magnification, the wafer rotation, the non-orthogonality, and/or the wafer translation.

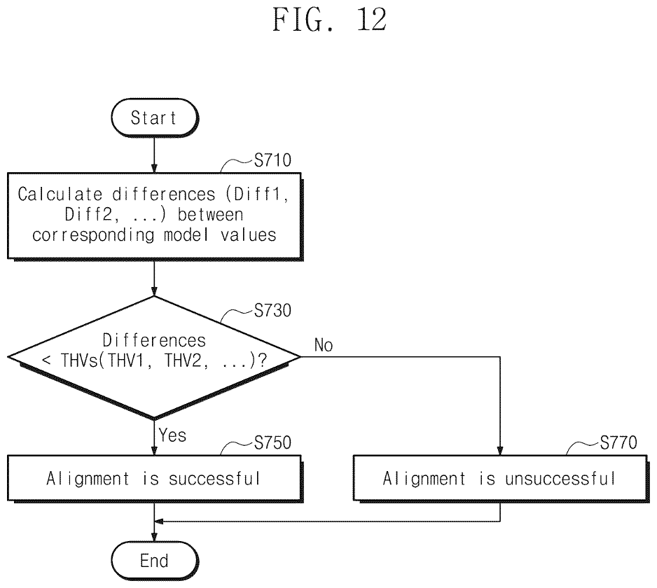

FIG. 12 is a flowchart illustrating an example embodiment of an operation of the alignment verifier of FIG. 5.

Referring to FIG. 12, differences (e.g., Diff1, Diff2, . . .) between corresponding model values may be calculated (S710). In other words, differences between model values CRS_MDVs of a first coarse model parameter among the plurality of coarse model parameters CRS_M_PARAMs and respective ones of model values FI_MDVs of the fine model parameter FI_M_PARAMs corresponding thereto, may be calculated. In some example embodiments, a coarse model parameter (including a first model value and a second model value) may be generated by performing the COWA and a file model parameter (including a first model value and a second model value) may be generated by performing the FIWA, and whether the alignment of the semiconductor wafer is successful may be determined by determining whether a difference between the first model value and the third model value is less than a first threshold value and by determining whether a difference between the second model value and the fourth model value is less than a second threshold value. The first threshold value and the second threshold value may be empirically determined. The first model value and the third model value may be model values associated with a wafer magnification, and the second model value and the fourth model value may be model values associated with a wafer rotation.

It may be determined whether the differences between the corresponding model values are less than corresponding threshold values (e.g., THV1, THV2, . . . ), respectively (S730).

When the differences are less than the threshold values (S730: YES), the alignment for the semiconductor wafer may be determined to be successful (S750), and when the differences are greater than or equal to the threshold values (S730: NO), the alignment for the semiconductor wafer may be determined to be unsuccessful (S770).

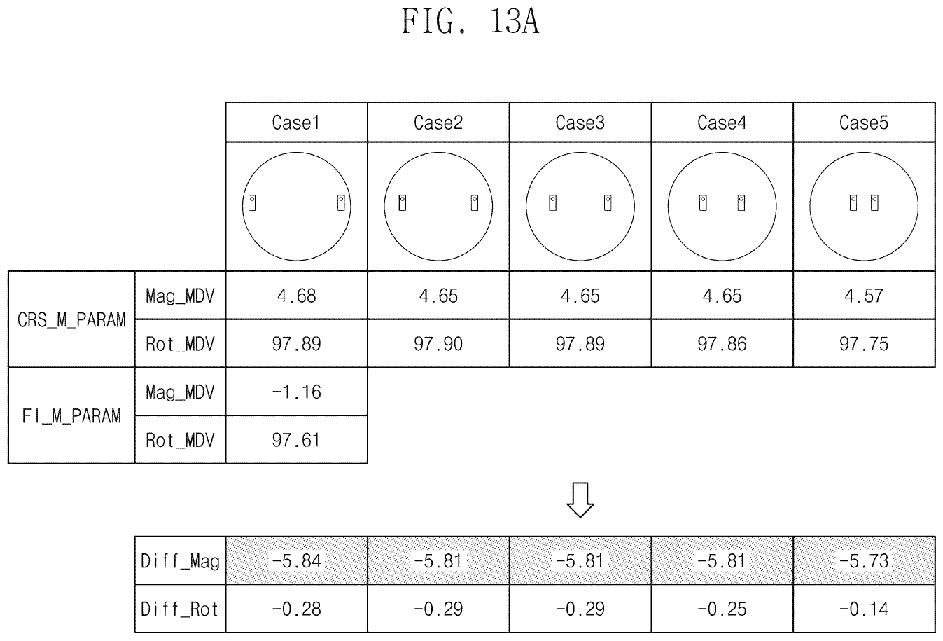

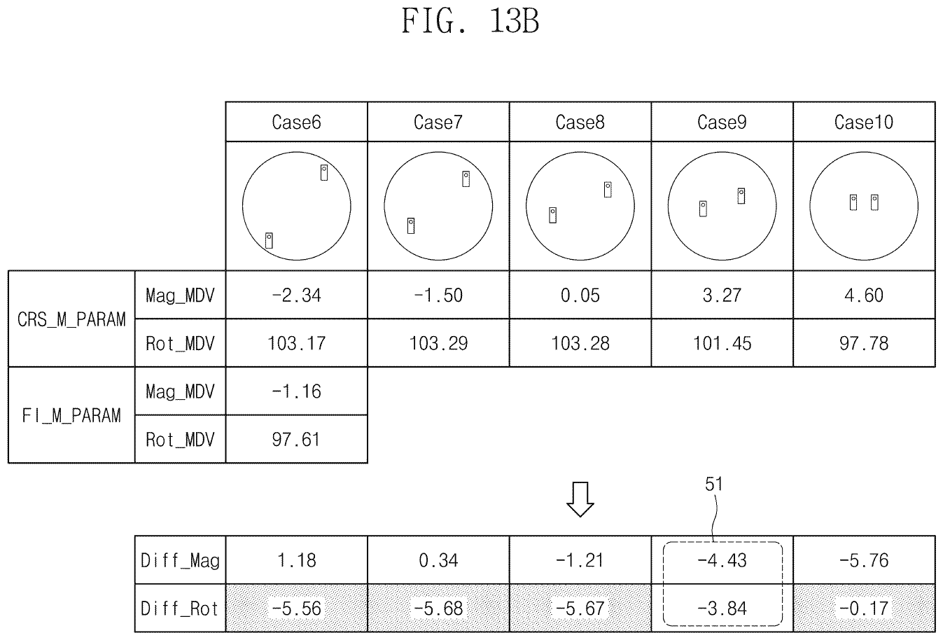

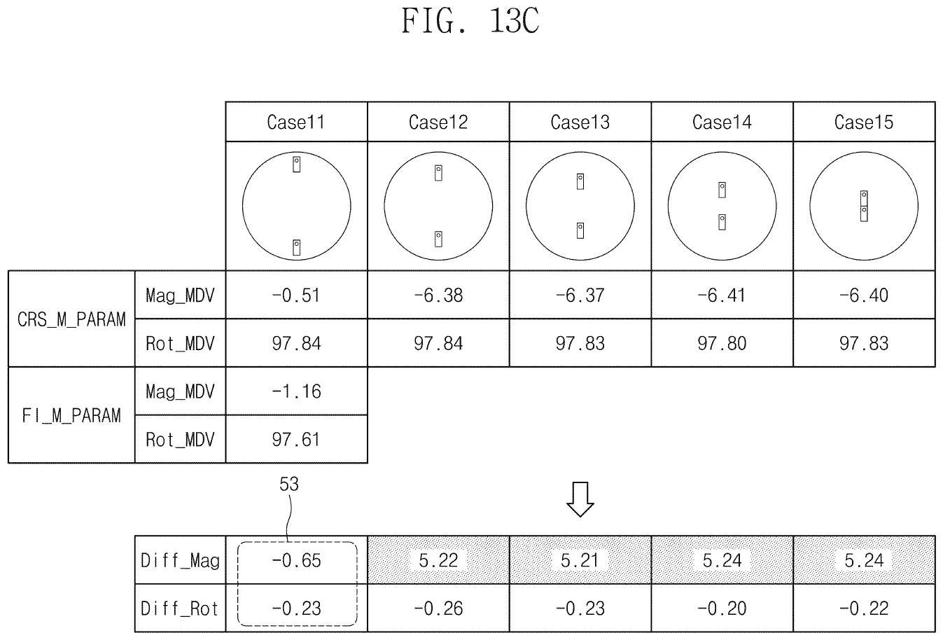

FIGS. 13A, 13B, and 13C are diagrams for describing a process for determining whether alignment of a semiconductor wafer is successful.

In FIG. 13A, FIG. 13B and FIG. 13C, Case1, Case2, Case3, Case4, Case5, Case6, Case7, Case8, Case9, Case10, Case11, Case12, Case13, Case14, and Case15 are illustrated. In Case1 to Case15, the COWA and the FIWA may be performed on the plurality of mark pairs set in a similar manner to the manner described above with reference to FIG. 10. The coarse model parameter CRS_M_PARAM and the fine model parameter FI_M_PARAM may include model values Mag_MDV and Rot_MDV. The model value Mag_MDV may be a value related to the wafer magnification and may be expressed in units of micrometer (μm), and the model value Rot_MDV may be a value related to the wafer rotation and may be expressed in units of micro radian (μrad).

In an example embodiment, a difference Diff_Mag between the model value Mag_MDV of the coarse model parameter CRS_M_PARAM and the model value Mag_MDV of the fine model parameter FI_M_PARAM may be calculated. A difference Diff_Rot between the model value Rot_MDV of the coarse model parameter CRS_M_PARAM and the model value Rot_MDV of the fine model parameter FI_M_PARAM may be calculated. For example, in Case1, the difference Diff_Mag may be −5.84 μm and the difference Diff_Rot may be calculated as −0.28 μrad. In Case2, the difference Diff_Mag may be −5.81 μm and the difference Diff_Rot may be calculated as −0.29 μrad. In Case3, the difference Diff_Mag may be −5.81 μm and the difference Diff_Rot may be calculated as −0.29 μrad. Cases 4 to 15 may also be calculated in the same manner as Cases 1 to 3.

In an example embodiment, the threshold associated with the difference Diff_Mag may be set to 5 μm and the threshold associated with the difference Diff_Rot may be set to 5 μrad. For example, the shaded values in the differences Diff_Mag and Diff_Rot of FIGS. 13A, 13B and 13C may represent values greater than or equal to the threshold values, and the alignments of the semiconductor wafers in Cases 9 and 11 corresponding to the differences Diff_Mag and Diff_Rot 51 and 53 may be determined to be successful.

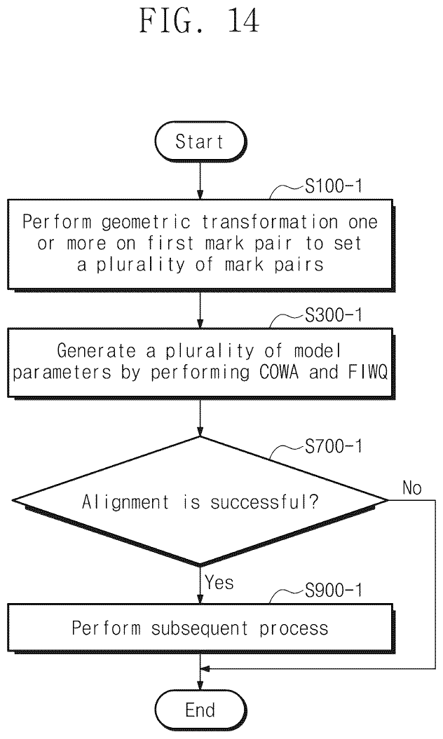

FIG. 14 is a flowchart illustrating a semiconductor wafer alignment method, according to an example embodiment of the present disclosure.

Referring to FIG. 14, a plurality of mark pairs including the first mark pair may be set by performing the geometric transformation at least once on the first mark pair (S100-1).

In an example embodiment, S100-1 may correspond to S100 described above with reference to FIG. 3.

A plurality of model parameters may be generated by performing the COWA and the FIWA based on the plurality of mark pairs and the plurality of marks (S300-1).

In an example embodiment, S300-1 may correspond to S300 and S500 described above with reference to FIG. 3.

Based on the plurality of model parameters, it may be determined whether the alignment of the semiconductor wafer is successful (S700-1).

In an example embodiment, the plurality of model parameters may include a plurality of coarse model parameters and a fine model parameter. Each of the plurality of coarse model parameters may include model values, the fine model parameter may also include model values, and based on differences between the corresponding model values in the model values of the plurality of coarse model parameters and the model values of the fine model parameter, it may be determined whether the alignment of the semiconductor wafer is successful.

Based on the determination that the alignment of the semiconductor wafer is successful (S700-1: YES), a subsequent process may be performed (S900-1).

In an example embodiment, S700-1 and S900-1 may correspond to S700 and S900 described above with reference to FIG. 3, respectively.

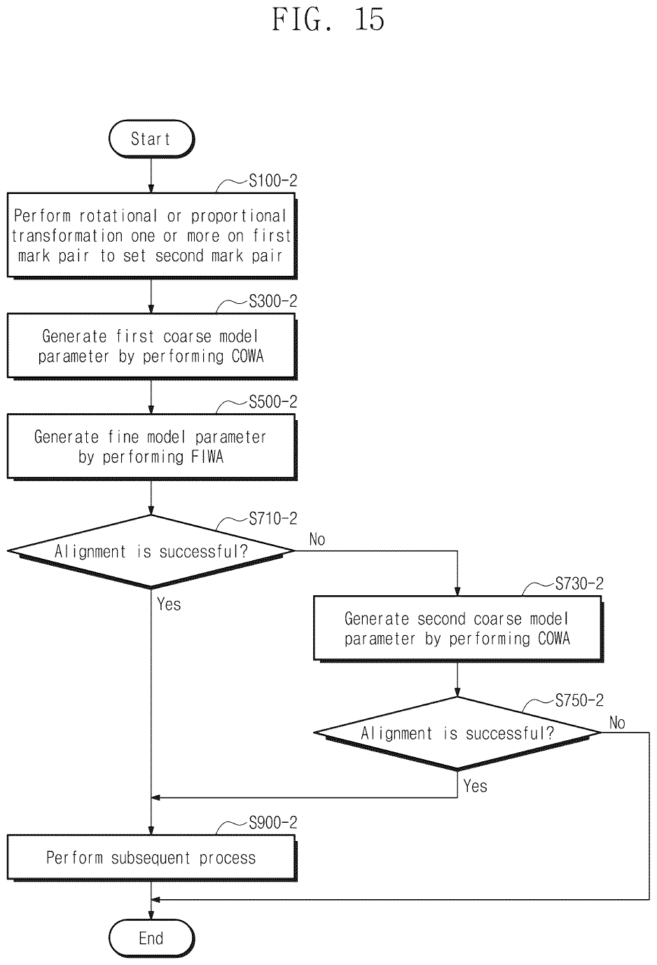

FIG. 15 is a flowchart illustrating a semiconductor wafer alignment method, according to an example embodiment of the present disclosure.

Referring to FIG. 15, a second mark pair may be set by performing the rotational transformation or the proportional transformation at least once on the first mark pair (S100-2).

A first coarse model parameter may be generated by performing the COWA based on the first mark pair (S300-2).

Based on the plurality of marks, the FIWA may be performed to generate the fine model parameter (S500-2).

Whether the alignment of the semiconductor wafer is successful may be determined based on the first coarse model parameter and the fine model parameter (S710-2).

Based on the determination that the alignment of the semiconductor wafer is not successful (S710-2: NO), a second coarse model parameter may be generated by performing the COWA based on the second mark pair (S730-2).

Whether the alignment of the semiconductor wafer is successful may be determined based on the second coarse model parameter and the fine model parameter (S750-2).

Based on the determination that the alignment of the semiconductor wafer is successful (S710-2: YES or S750-2: YES), a subsequent process may be performed (S900-2).

In an example embodiment, as described above with reference to FIG. 7, only the COWA for the first mark pair is performed, whether the alignment of the semiconductor wafer is successful is determined based on the result of performing the COWA on the first mark pair, and when the alignment of the semiconductor wafer is not successful, the second mark pair may be generated and the COWA for the second mark pair may be performed.

According to an example embodiment of the present disclosure, in a semiconductor wafer alignment method, the scanner device may select some of a plurality of marks of a semiconductor wafer to perform the coarse wafer alignment (COWA) and to perform the fine wafer alignment (FIWA) on the plurality of marks. The selection of some of the plurality of marks for the COWA may affect the model values that the coarse model parameters may have, thereby affecting the success or the failure of the semiconductor wafer alignment. The scanner device may improve the success rate of the semiconductor wafer alignment by selecting the marks for the COWA according to the alignment method of the semiconductor wafer according to the example embodiments of the present disclosure, considering the shape that the semiconductor wafer may have. Therefore, subsequent processes of the semiconductor wafer, including the exposure process, may proceed more smoothly.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

The above descriptions are illustrative of some example embodiments for carrying out the present disclosure. Some example embodiments in which a design is slightly changed or which are easily changed may be included in the present disclosure as well as the example embodiments described above. In addition, technologies that are easily changed and implemented by using the above example embodiments may be included in the present disclosure. Therefore, the scope of the present disclosure should not be limited to the above-described example embodiments and should be defined by not only the claims to be described later, but also those equivalent to the claims of the present disclosure.

What is claimed is:

1. A method of aligning a semiconductor wafer in a scanner device, the method comprising:
performing a geometric transformation at least once on a first mark pair including two marks among a plurality of marks of a semiconductor wafer to set a plurality of mark pairs including the first mark pair;
performing a coarse wafer alignment (COWA) based on each of the plurality of mark pairs to generate a plurality of coarse model parameters;
performing a fine wafer alignment (FIWA) based on the plurality of marks to generate a fine model parameter;
determining whether an alignment of the semiconductor wafer is successful based on the plurality of coarse model parameters and the fine model parameter; and
performing a subsequent process based on a determination that the alignment of the semiconductor wafer is successful.

2. The method of claim 1, wherein the setting the plurality of mark pairs includes:
selecting two marks being at a same distance from a center of the semiconductor wafer to generate the first mark pair;
performing a rotational transformation once on the first mark pair based on the center of the semiconductor wafer to generate a second mark pair; and
generating the plurality of mark pairs including the first mark pair and the second mark pair.

3. The method of claim 2, wherein the setting the plurality of mark pairs further includes:
performing the rotational transformation once on the second mark pair to generate a third mark pair; and
generating the plurality of mark pairs including the first mark pair, the second mark pair, and the third mark pair.

4. The method of claim 3, wherein a rotation angle depending on the rotational transformation with respect to the first mark pair is same as a rotation angle depending on the rotational transformation with respect to the second mark pair.

5. The method of claim 2, wherein
a number of the plurality of mark pairs is “N” (where “N” is an integer greater than or equal to 2), and
a rotation angle depending on the rotational transformation with respect to the first mark pair is 360/N degrees.

6. The method of claim 1, wherein the setting the plurality of mark pairs includes:
performing a proportional transformation once on the first mark pair to generate a second mark pair; and
generating the plurality of mark pairs including the first mark pair and the second mark pair.

7. The method of claim 6, wherein the setting the plurality of mark pairs further includes:
performing the proportional transformation once on the second mark pair to generate a third mark pair; and
generating the plurality of mark pairs including the first mark pair, the second mark pair, and the third mark pair.

8. The method of claim 7, wherein a reduction ratio depending on the proportional transformation with respect to the first mark pair is less than a reduction ratio depending on the proportional transformation with respect to the second mark pair.

9. The method of claim 7, wherein a reduction ratio depending on the proportional transformation with respect to the first mark pair is same as a reduction ratio depending on the proportional transformation with respect to the second mark pair.

10. The method of claim 1, wherein each of the plurality of coarse model parameters includes model values associated with a wafer magnification, a wafer rotation, a non-orthogonality, and/or a wafer translation.

11. The method of claim 1, wherein the determining whether the alignment of the semiconductor wafer is successful includes:
calculating differences between model values of a first coarse model parameter among the plurality of coarse model parameters and model values of the fine model parameter corresponding thereto, respectively; and
determining whether the differences are less than corresponding threshold values, respectively, to determine whether the alignment of the semiconductor wafer is successful.

12. The method of claim 1, wherein each of the plurality of mark pairs includes two marks arranged at a same distance from a center of the semiconductor wafer.

13. The method of claim 1, further comprising:
performing a wafer bonding process of bonding one semiconductor sub-wafer to another semiconductor sub-wafer to provide the semiconductor wafer.

14. The method of claim 1, wherein
the semiconductor wafer includes a plurality of shot regions, and
a number of the plurality of marks is greater than or equal to a number of the plurality of shot regions.

15. A method of aligning a semiconductor wafer in a scanner device, the method comprising:
performing a geometric transformation at least once on a first mark pair including two marks among a plurality of marks of a semiconductor wafer to set a plurality of mark pairs including the first mark pair;
performing a coarse wafer alignment (COWA) and a fine wafer alignment (FIWA) based on the plurality of mark pairs and the plurality of marks to generate a plurality of model parameters;
determining whether an alignment of the semiconductor wafer is successful based on the plurality of model parameters; and
performing a subsequent process based on a determination that the alignment of the semiconductor wafer is successful.

16. The method of claim 15, wherein
the generating the plurality of model parameters includes:
generating a coarse model parameter by performing the COWA, and
generating a fine model parameter by performing the FIWA, and
the coarse model parameter includes a first model value and a second model value,
the fine model parameter includes a third model value and a fourth model value, and
the determining whether the alignment of the semiconductor wafer is successful includes
determining whether a difference between the first model value and the third model value is less than a first threshold value, and
determining whether a difference between the second model value and the fourth model value is less than a second threshold value.

17. The method of claim 16, wherein
the first model value and the third model value are model values associated with a wafer magnification, and
the second model value and the fourth model value are model values associated with a wafer rotation.

18. The method of claim 15, wherein each of the plurality of mark pairs includes two marks arranged at a same distance from a center of the semiconductor wafer.

19. The method of claim 15, wherein
the semiconductor wafer includes a plurality of shot regions, and
a number of the plurality of marks is greater than or equal to a number of the plurality of shot regions.

20. A method of aligning a semiconductor wafer in a scanner device, the method comprising:
performing a rotational transformation or a proportional transformation at least once on a first mark pair including two marks among a plurality of marks of a semiconductor wafer to set a second mark pair;
performing a coarse wafer alignment (COWA) based on the first mark pair to generate a first coarse model parameter;
performing a fine wafer alignment (FIWA) based on the plurality of marks to generate a fine model parameter;
determining whether an alignment of the semiconductor wafer is successful based on the first coarse model parameter and the fine model parameter;
performing a COWA based on the second mark pair to generate a second coarse model parameter based on a determination that the alignment of the semiconductor wafer is not successful; and
determining whether the alignment of the semiconductor wafer is successful based on the second coarse model parameter and the fine model parameter.
